(19) United States
(12) Patent Application Publication
(10) Pub. No.: US 2026/0229460 A1
(43) Pub. Date: Aug. 6, 2026

(54) Power Generators and Methods of Using the Same

(71) Applicant: Advanced Energy Industries, Inc., Denver, CO (US)

(72) Inventors: Anthony Lee Lecher, Goodyear, AZ (US); Philip Charles Schmitt, Fort Collins, CO (US); Suryan Emani, San Jose, CA (US)

(73) Assignee: Advanced Energy Industries, Inc., Denver, CO (US)

(21) Appl. No.: 19/007,341

(22) Filed: Dec. 31, 2024

(51) Int. Cl. H01J 37/32; H03F 3/24; H03H 7/38

(52) U.S. Cl. CPC H01J 37/32183; H03F 3/245; H03H 7/38; H03F 2200/451

(57) ABSTRACT

A system may include an exciter to provide a signal comprising a frequency. A system may include an amplifier to amplify the signal to provide an amplified signal. A system may include a match network to adjust an impedance of the system to at least one non-fifty-ohm match state. A system may include a controller to adjust the frequency.

### FIELD OF THE DISCLOSURE

The present disclosure relates generally to power supplies. In particular, but not by way of limitation, the present disclosure relates to power supplies, such as radio frequency generators, used in plasma processing applications.

### BACKGROUND

Power supplies, such as radio frequency (RF) generators, are known to be used to produce a plasma in connection with plasma processing systems. Plasma processing systems may be used to perform etching and/or deposition.

Plasma etching and deposition are often used in semiconductor manufacturing processes. In plasma etching, ions are accelerated by an electric field to etch exposed surfaces on the substrate. An electric field is generated based on RF power signals generated by one or more radio frequency (RF) generators of an RF power system.

### SUMMARY OF THE DISCLOSURE

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In some aspects, the techniques described herein relate to a system comprising: an exciter to provide a signal including a frequency; an amplifier to amplify the signal to provide an amplified signal; a match network to adjust an impedance of the system to at least one non-fifty-ohm match state; and a controller to adjust the frequency.

In some aspects, the techniques described herein relate to a system, wherein the match network is configured to match to two or more non-fifty-ohm match states.

In some aspects, the techniques described herein relate to a system, wherein the match network includes two PIN diodes to provide at least four match states.

In some aspects, the techniques described herein relate to a system, wherein the exciter, the amplifier, the match network, and the controller are housed within a same chassis.

In some aspects, the techniques described herein relate to a system, including DC protection circuitry to receive DC power from a DC power supply that is remote from the chassis.

In some aspects, the techniques described herein relate to a system, including a DC power supply within the same chassis to provide power to, at least, the amplifier.

In some aspects, the techniques described herein relate to a system including: a DC power supply to remotely power a plurality of power amplifiers via a DC bus.

In some aspects, the techniques described herein relate to a system, including a sensor to sense current provided by the system, wherein the controller is configured to adjust the sensed current.

In some aspects, the techniques described herein relate to a system, including a sensor to sense voltage, wherein the controller is configured to adjust the sensed voltage.

In some aspects, the techniques described herein relate to a system including: an oscillator to provide a radio frequency signal; at least one amplifier to amplify the radio frequency signal to produce at least one amplified radio frequency signal; and a controller to regulate on at least one of current and voltage of the at least one amplified radio frequency signal.

In some aspects, the techniques described herein relate to a system including: a match network configured to match the amplifier to at least one non-fifty-ohm match state.

In some aspects, the techniques described herein relate to a system, wherein the controller is configured to control the exciter to adjust the frequency of the amplified radio frequency signal.

In some aspects, the techniques described herein relate to a system, wherein the match network is configured to match to two or more non-fifty-ohm match states.

In some aspects, the techniques described herein relate to a system including a distributed direct current (DC) system configured to power a plurality of amplifiers.

In some aspects, the techniques described herein relate to a system, including: a housing enclosing the exciter and the amplifier; wherein the distributed DC system includes a DC power supply that is external to the housing, the DC power supply to power the plurality of amplifiers.

In some aspects, the techniques described herein relate to a system including: a plurality of generators wherein each generator is configured to mechanically couple on chamber, wherein each generator provides an amplified signal, each generator including: a match network; and a direct current (DC) system to power the plurality of generators.

In some aspects, the techniques described herein relate to a system wherein the match network of each generator is configured to match to at least one non-fifty-ohm match state.

In some aspects, the techniques described herein relate to a system wherein the match network of each generator is configured to match to two or more non-fifty-ohm match states.

In some aspects, the techniques described herein relate to a system, wherein each generator includes an exciter to provide a signal and a controller configured to control a corresponding exciter to adjust a frequency of the signal.

In some aspects, the techniques described herein relate to a system, wherein each generator includes a controller to regulate a corresponding amplified signal on at least one of current and power.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1 illustrates a system-level view of a system for providing a waveform to a processing chamber.

FIG. 2 is a block diagram providing additional details of DC power distribution and control.

FIG. 3 is a block diagram illustrating additional details of frequency control and match control.

FIG. 4 is a diagram depicting examples of subcomponents of a generator.

FIG. 5 is a block diagram depicting examples of components that may be used in a controller.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the architecture, functionality, and operation of possible implementations of systems, methods and computer program products according to various embodiments of the present disclosure. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein. Unless otherwise limited, “coupled” means directly and indirectly coupled.

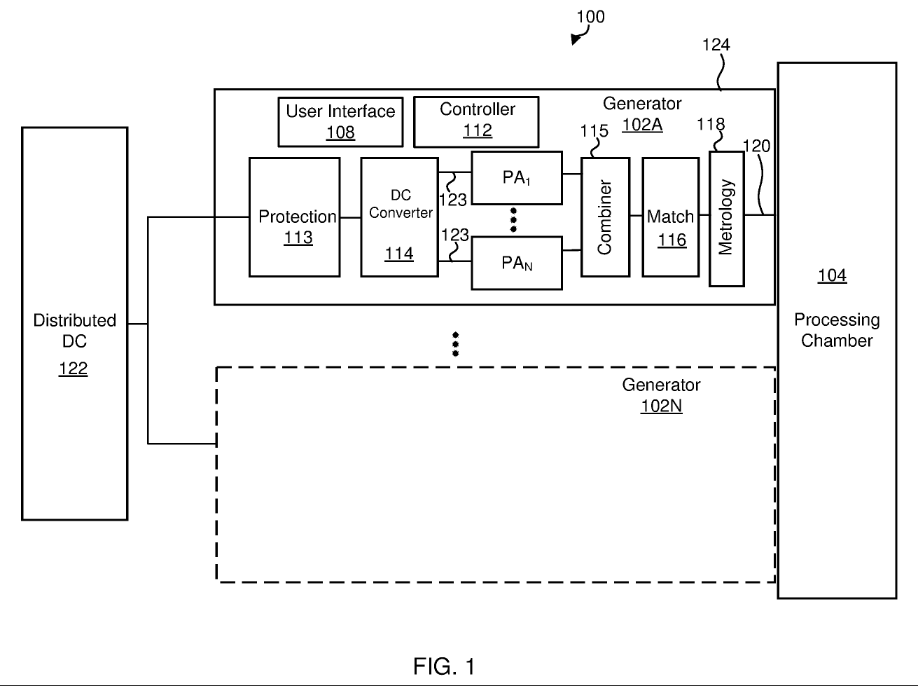

Embodiments disclosed herein provide functions and benefits previously unavailable by way of structural and/or operational aspects. Many of these aspects may be explained with reference to FIG. 1, which illustrates a system-level view of a system 100 comprising a generator 102 for providing, e.g., responsive to a user-defined output, a waveform to processing chamber 104, which may present a nonlinear plasma load to generator 102. Generator 102 can include a user interface 108, a controller 112, protection 113, at least one power amplifier (PA) 106, a combiner 115, a match network 116, and metrology 118, which is coupled to output 120. In some instances, the system 100 may include a single generator 102. In other instances, the system 100 may include two or more generators, where each of the generators 102A-102N may be substantially configured (e.g., may include the same or similar hardware and/or software) as depicted for generator 102A. The system 100 may include distributed direct current (DC) 122 that provides DC power to the N generators, where N is one or more, via distributed DC 122. As one of ordinary skill in the art will appreciate, if there is a single power amplifier, PA, then the combiner 115 is not necessary. The combiner 115 may be a radio frequency (RF) combiner and may be constructed with any of a variety of topologies such as, without limitation, a hybrid combiner.

Before detailing several design and operational aspects, it is helpful to understand the general operation of the depicted system 100. In operation, the distributed DC 122 may convert alternating current (AC) power (e.g., from AC mains of the premises where the system is deployed) to direct current (DC) power that is provided to each of the generators 102. The DC power is fed to DC converter 114 via protection 113, which is configured to couple DC power from the distributed DC 122 to the generator 102 in normal operation and decouple the generator 102 from the distributed DC 122 when a fault condition is detected. The DC converter 114 may be realized by a variety of alternative power conversion topologies, such as any of a variety of DC-to-DC converter topologies. For example, the DC converter 114 may be realized by a linear regulator, a buck converter, a boost converter, a buck-boost converter, and/or other types of regulators and converters. DC converter 114 may provide and distribute DC power 123 to circuits of the generator 102. For example, DC converter 114 may couple to a supply rail of the power amplifier(s), PA_{N},to drive the rail voltage of each amplifier, PA_{N}, and there may be a combiner 115 coupled to the amplifiers, PA_{N}, to combine the amplified signals that are output by the power amplifiers, PA_{N}.

As shown, the generator 102 in this example comprises N power amplifiers, PA_{N}, where N is one or more. In embodiments where there are two or more amplifiers, PA_{N,} the amplified signals from the amplifiers, PA_{N,} are combined to produce an amplified signal. The amplified signal is provided to a match network 116 that may function to center the source characteristic impedance of the generator 102 to the characteristic impedance of the processing chamber 104. As discussed further herein, match network 116 may provide one or more characteristic impedance states to match the source impedance of the generator 102 to the processing chamber 104. As those of ordinary skill in the art will appreciate in view of this disclosure, the processing chamber 104 may present a variable impedance that deviates from the fifty-ohm standard impedance of a traditional RF circuit and interconnect components (e.g., fifty-ohm cables). The match network 116 may be tuned to a match state, of a set of one or more possible match states, in order to improve matching between the generator 102 and the (non-fifty-ohm impedance) chamber 104. Accordingly, the match network 116 may improve (e.g., increase) the amount of power coupled to the chamber 104 from the generator 102.

As discussed further herein, generator 102 may be mechanically coupled directly to the processing chamber 104. More specifically, unlike prior art systems that couple a generator to a plasma processing chamber via a fifty-ohm cable, a match network, and another fifty-ohm cable, the generator 102 may be directly coupled to the processing chamber 104 (such as depicted in FIG. 1) to avoid the cable-match-cable coupling of prior art systems. Although the mechanical coupling may vary depending upon a design of the processing chamber 104, each generator may be bolted on to the processing chamber 104. The electrical coupling between each generator 102 and the processing chamber may also vary depending upon a design of electrical input(s) to the processing chamber 104, but the output 120 of each generator 102 may electrically couple to the processing chamber 104 via a pin-and-socket connection to avoid use of a cable (e.g., a fifty-ohm cable). Accordingly, the configurations described herein may improve coupling between the generator 102 and chamber 104 and may eliminate unnecessary components in the system 100 (e.g., may eliminate the need for cabling and additional match networks).

Several inventive aspects are disclosed herein, and these inventive aspects may be combined in various combinations. Some aspects disclosed herein comprise distributed DC 122 that provides a DC bus to one or more of the generators 102. As discussed further herein, the distributed DC 122 may be remotely located from the generator(s) 102 (such as depicted in FIG. 1) so that a bulky power supply is not physically mounted to the processing chamber with the generator(s) 102. Another aspect disclosed herein is utilization of frequency tuning in a single non-fifty-ohm chassis (e.g., within a single housing 124, where the housing may comprise metallic components) that is directly coupled to the processing chamber 104. Yet another aspect is frequency tuning utilized with one or more non-fifty-ohm match states provided by the match network 116. Another inventive aspect discussed further herein comprises, in contrast to regulating power, regulating current and/or voltage at an output of the generator(s) 102. It should be recognized that these aspects are not mutually exclusive and that none of the examples provided further herein with reference to FIGS. 1-5 should be assumed to be mutually exclusive. In other words, the aspects described with reference to FIGS. 1-5 may be combined to produce variations of the system 100, generator 102, and distributed DC 122. It is also contemplated that two or more of the generators may be housed in a common housing.

In connection with the various inventive combinations disclosed herein, the controller 112 may be configured to simultaneously control gain, frequency, and aspects of the match network 116 of one or more generators 102 in connection with one or more input parameter values such as, without limitation, power, voltage, and/or current. As used herein, “configured to” describes a specific adaptation to hardware and/or software to the controller 112 to enable the controller 112 to operate as described herein. It is also contemplated that metrology 118 may be configured to allow a single measurement point to enable control of power, current, and/or voltage delivered to the processing chamber 104. This approach provides an improvement to enable distinguishing between different frequencies and near frequency (in band) separation utilizing feedforward and/or feedback between controller 112 and metrology 118.

As those of ordinary skill in the art will appreciate, metrology 118 may comprise one or more sensors such current transducers, voltage sensors, VI sensors, and/or directional couplers. Metrology 118 may also include hardware to sample and digitize analog signals provided by the sensors. Although not shown in FIG. 1, metrology 118 may be coupled to controller 112 to provide signals to the controller 112 that are indicative of, for example and without limitation, power, current, voltage, current-voltage phase, complex forward power, and/or complex reflected power.

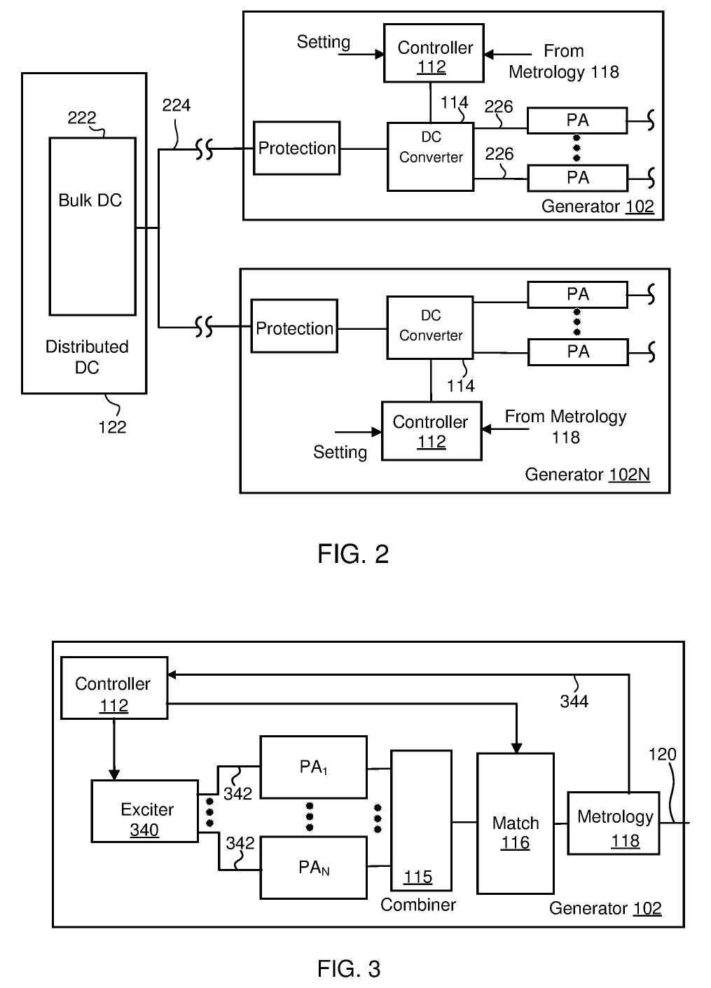

Referring next to FIG. 2, shown is a block diagram depicting aspects of DC power distribution and control of the system depicted in FIG. 1. As shown, distributed DC 122 comprises bulk DC 222 that sets up a DC bus 224 that feeds DC power to each of N generators where N is one or more. The distributed DC 122 may include one or more types of DC-DC converters, such as buck, boost, buck-boost, and/or other types of converters. In addition, distributed DC 122 may include established power supply components, such as various switching components, magnetic components (e.g., transformers, inductors, etc.), protection circuitry (e.g., various current protections, voltage protections, electronic fuse, etc.), measurement circuitry, control circuitry (e.g., one or more processing elements), etc. Distributed DC 122 may comprise a single output (as depicted) or multiple outputs. In embodiments where distributed DC 122 comprises multiple outputs, bus 224 may comprise a separate connection (e.g., power supply cable) between the distributed DC 122 and each generator 102A-102N. Distributed DC 122 may include internal thermal monitoring and protection. The protection/protection circuitry of the distributed DC 122 may operate independently of protection 113 provided in each of the generators 102A-102N or may work in conjunction with protection 113 to provide protection (voltage, current, thermal, etc.). Distributed DC 122 may provide capability to receive one or more input signals from one or more of the generators 102A-102N. The distributed DC 122 may use the received input signals to regulate output voltage, current, power, and/or other aspects of the output of distributed DC 122. For example, the distributed DC 122 may receive signals provided by controller 112, protection 113, and/or other component of a generator 102A-102N, and may use the received signals as described.

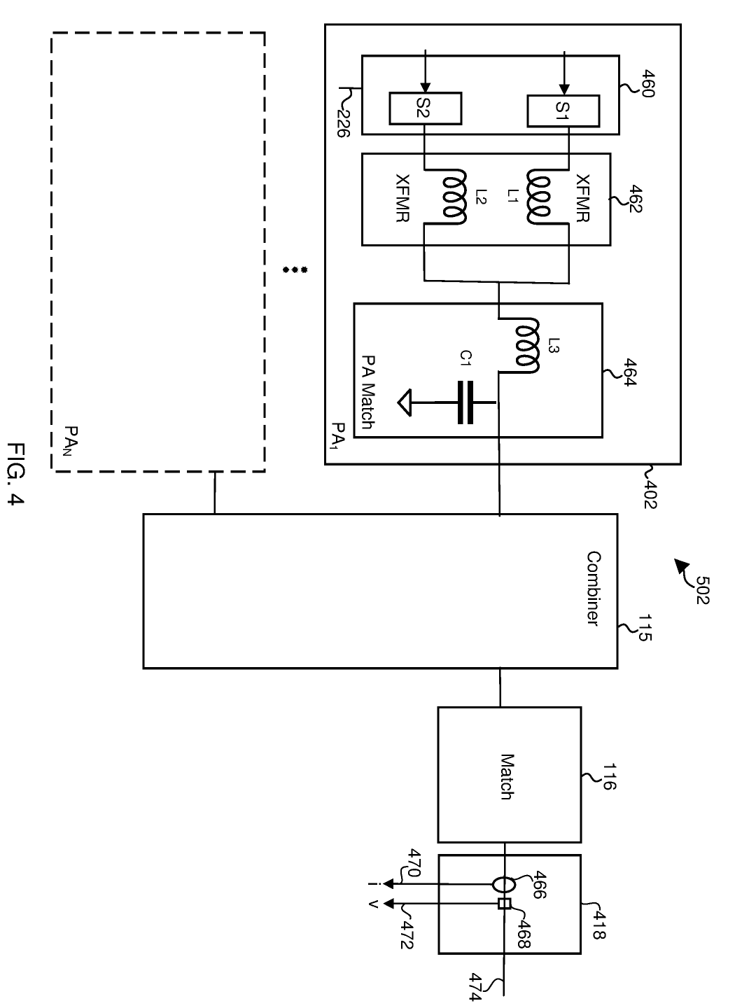

Referring next to FIG. 3, shown is a block diagram depicting an aspect of frequency tuning that may be utilized by generator 102 (that is configured to have a non-fifty-ohm source impedance). As shown, controller 112 is coupled to a driver exciter 340 to control, responsive to feedback 344 from metrology 118, the frequency of radio frequency signals 342 that are provided to the power amplifiers, PA_{N}. The exciter 340 may comprise an oscillator and/or a signal generator, for example. Although not shown in FIG. 3, one of ordinary skill in the art will appreciate that the phase of radio frequency signals 342 may be offset from one another (e.g., by forty-five degrees). The feedback 344 from metrology 118 may include one or more power-related signals including, without limitation, voltage signals indicative of voltage at output 120, current signals indicative of current provided at output 120, and/or signals indicative of phase between the voltage and the current at output 120. In some embodiments, the feedback 344 from metrology 118 may also comprise feedback indicative of forward and reflected power that is provided by a directional coupler.

In some variations, the match network 116 is configured to provide one or more non-fifty-ohm match states. As one or ordinary skill in the art (in view of this disclosure) will appreciate, the match states may be, for example, achieved by solid state match elements. For example, discrete switching of PIN diodes may be used to switch reactive elements (e.g., capacitors) into and out of the match network 116. One of ordinary skill in the art will appreciate that variable vacuum capacitors may be used in connection with discrete switching of reactive elements, or variable vacuum capacitors may be used instead of discrete switching of capacitors.

In operation, the processing chamber 104 may present a range of impedances in which the processing chamber 104 may vary during operation. An aspect of embodiments herein is improving energy delivery while reducing power amplifier dissipation. The match network 116 may be designed to center to an impedance presented by the processing chamber 104 within this range, and then frequency tuning may be used during processing to adapt to the varying load presented by the processing chamber 104. For example, the exciter 340 may be controlled to initially set a frequency of radio frequency signals 342 to an initial frequency (for example and without limitation 13.56 MHz), and then the exciter 340 may be controlled to adjust the frequency up or down in response to the feedback 344 from metrology. As one of ordinary skill in the art will appreciate in view of this disclosure, changing the frequency of the radio frequency signals 342 changes the impedance of the match network 116, so frequency may be used with settings of the match network 116 to achieve a desired source impedance for each generator 102,

In addition, the match network 116 may be designed to operate in various modes in connection with frequency tuning. For example, the match network 116 may be designed to set imaginary impedance only (e.g., without a real impedance component); the match network 116 may be designed to set the real and imaginary impedance or the match network 116 may be designed with switchable real impedance and/or switchable real and imaginary impedance; and the match network 116 may be designed with tunable real and/or imaginary impedance.

It is contemplated that, to account for the imaginary impedance, (+/- J), the controller 112 may be configured to adjust the frequency of the radio frequency signals 342 to tune to an output resonance of the load of the processing chamber 104. In prior tuning approaches, frequency tuning was adjusted to achieve zero reflected power to best match an input impedance of a match network, but this type of tuning does not necessarily mean better impedance matching to the load of the processing chamber 104. For implementations where the generator 102 is directly coupled to the processing chamber 104, the power amplifier(s), PA_{N}, may be forced into a non-resonant mode at the power amplifiers, PA_{N}, so that power delivery is more closely optimized to the load of the processing chamber 104.

Referring to FIG. 4, shown is an example of a generator 402 that may be used to realize aspects of the generators 102 disclosed herein. As shown, a power amplifier, PA, may comprise a switch section 460, a transformer module 462, a PA match 464. The power amplifier, PA, may be coupled to the combiner 115, which is further coupled to the match network 116. In this example, the switch section 460 may include one or more switches (e.g., field effect transistors (FETs)), such as switches S1 and S2,that may operate in switch mode in connection with the DC rail voltage 226 to amplify the radio frequency signal 342 responsive to control signals from controller 112 to regulate current 470 and/or voltage 472 of output 474 based upon voltage measurements indicative of voltage 472 (e.g., from a voltage sensor 468 of metrology 418) and/or current measurements 470 indicative of current (e.g., with a current transducer 466 (also referred to as a current sensor) of metrology 418). As one of ordinary skill in the art will appreciate in view of this disclosure, the switch section 460 may operate as a class D and/or a class E amplifier. As one of ordinary skill in the art will appreciate, metrology 418 may be designed in various ways just as metrology 118 may be designed in various ways.

It should be recognized that two switches in the switch section are shown only as an example and that one of ordinary skill in the art will appreciate that one switch or more than two switches may be implemented in variety of topologies. For example and without limitation, full bridge (e.g., an H-bridge) and/or half-bridge topologies may be utilized in the switch section 460.

In some variations of the generator 402, the transformer module 462, the PA match 464, the combiner 115, and the match network 116 may be designed and/or or configured as swappable modules (e.g., a module may be removed and replaced with a similar module configured for different operation) so the generator 402 may be easily configured to match with different processing chambers 104. An overall design goal may be to match a natural impedance of the switch section 460 (which may comprise laterally-diffused metal-oxide semiconductor (LDMOS) field effect transistors) to a load impedance of the processing chamber 104 without a transition to the typical 50 ohm standard (e.g., without an intervening fifty ohm cable or other fifty ohm circuit or component between the generator 402 and processing chamber 104). The typical output impedance of the switch section 460 may be 1 to 2 ohms (and up to 12 ohms), which may be very close to the .5 to 4 ohms of real impedance of a typical processing chamber 104. A switch section 460 exhibiting this range of output impedance allows a reduction in filtering and transformation components. In some variations, the match network 116 may be optimized to center to the impedance presented by the processing chamber 104.

The transformer module 462 may be designed (and/or selected from predesigned modules) to meet an impedance transformation which allows matching to a center of a resistance (“R”) range for the processing chamber 104 without a phase shift. It is also contemplated that the transformer module 462 may be modified to add an additional transformer to achieve an R match without utilizing other match components. As an example without limitation, the modules for the transformer module 462 may be designed as five ohm, ten ohm, twenty five ohm, and fifty ohm modules. It should also be recognized that the transformer module 462 depicted in FIG. 4 may be realized simply by the inherent inductance that couples the switches, S1, S2, to the PA match 464. It should also be recognized that the PA match 464 need not be implemented with an “L” topology, and that any topology may be utilized.

The power amplifier, PA, may be designed to allow delivered power to be achieved over a wide range of R impedance. For example, the power amplifier, PA, may be designed for a wider R range by setting an average delivered power to be less than a peak power of the power amplifier system. More specifically, without limitation, the peak power of a power amplifier may be designed to be six kW while the average delivered power is limited to three kW to allow three kW to be delivered across a wider R range. The higher peak power may be achieved by adding additional power amplifiers, PA_{N}, (to increase the value of N).

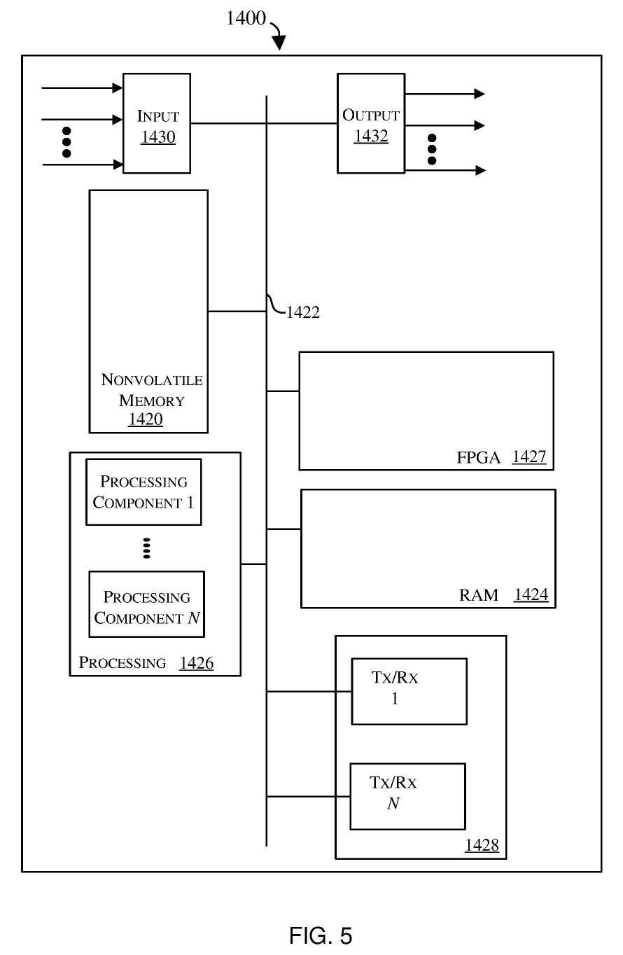

The methods described in connection with the embodiments disclosed herein may be embodied directly in hardware, in processor-executable code encoded in a non-transitory tangible processor readable storage medium, or in a combination of the two. Referring to FIG. 5 for example, shown is a block diagram depicting physical components that may be utilized to realize the controller 112 according to an exemplary embodiment. As shown, in this embodiment nonvolatile memory 1420 is coupled to a bus 1422 that is also coupled to random access memory ("RAM") 1424, a processing portion (which includes N processing components) 1426, a field programmable gate array (FPGA) 1427, and a transceiver component 1428 that includes N transceivers. None of these components are required, and any combination of these may be included. For instance, where an FPGA 1427 is implemented, the processing portion 1426 may not be used, and vice versa. Although the components depicted in FIG. 5 represent physical components, FIG. 5 is not intended to be a detailed hardware diagram; thus, many of the components depicted in FIG. 5 may be realized by common constructs or distributed among additional physical components. Moreover, it is contemplated that other existing and yet-to-be developed physical components and architectures may be utilized to implement the functional components described with reference to FIG. 5.

In general, the nonvolatile memory 1420 is non-transitory memory that functions to store (e.g., persistently store) data and processor-executable code (including executable code that is associated with effectuating the methods described herein). In some embodiments for example, the nonvolatile memory 1420 includes bootloader code, operating system code, file system code, and non-transitory processor-executable code to facilitate the execution of a method of, for example, frequency tuning and/or control of match network 116, as described herein.

In many implementations, the nonvolatile memory 1420 is realized by flash memory (e.g., NAND or ONENAND memory), but it is contemplated that other memory types may be utilized as well (e.g., read-only memory (ROM), NV-RAM, magnetic storage). Although it may be possible to execute the code from the nonvolatile memory 1420, the executable code in the nonvolatile memory is typically loaded into RAM 1424 and executed by one or more of the N processing components in the processing portion 1426.

The N processing components in connection with RAM 1424 generally operate to execute the instructions stored in nonvolatile memory 1420 to enable methods disclosed herein that are carried out by controller 112. For example, non-transitory, processor-executable code to effectuate the methods described herein may be persistently stored in nonvolatile memory 1420 and executed by the N processing components in connection with RAM 1424. As one of ordinarily skill in the art will appreciate, the processing portion 1426 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, the processing portion 1426 may be configured to effectuate one or more aspects of the methodologies described herein. For example, non-transitory processor-readable instructions may be stored in the nonvolatile memory 1420 or in RAM 1424 and when executed on the processing portion 1426, cause the processing portion 1426 to perform a method of controlling the frequency of radio frequency signals 342, DC rail voltage 226, and/or a position of match network 116.

In addition, the FPGA 1427 may include non-transitory processor-executable code to program the FPGA to facilitate functions disclosed herein. For example, the FPGA 1427 may be utilized by metrology 118 to sample and digitize measured power-related parameters (e.g., current, voltage, power, and reflected power). The FPGA 1427 may include on-board memory to access data such as the target multi-level waveform, or may access off-chip memory such as the nonvolatile memory 1420 accessible via bus 1422.

The input component 1430 operates to receive signals (e.g., feedback 344 from metrology 118, 418 and/or signals from the user interface 108 such as a target multi-level pulsed waveform) that are indicative of one or more aspects of the target waveform or conditions of the nonlinear plasma load of processing chamber 104. The signals received at the input component may include, for example, a measurement of voltage, current, and/or power delivered to the plasma processing chamber. The output component generally operates to provide one or more analog or digital signals to effectuate an operational aspect of the controller 112 generally. For example, the output portion 1432 may provide the controller signals to driver exciter 340 (as described with reference to FIG. 3) and the DC control 114 as described with reference to FIG. 2.

The depicted transceiver component 1428 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a "circuit," "module" or "system." Furthermore, aspects of the present invention may take the form of a computer program product embodied in one or more computer readable medium(s) having computer readable program code embodied thereon.

As used herein, the recitation of "at least one of A, B and C" is intended to mean "either A, B, C or any combination of A, B and C." The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A system comprising:
an exciter to provide a signal comprising a frequency;
an amplifier to amplify the signal to provide an amplified signal;
a match network to adjust an impedance of the system to at least one non-fifty-ohm match state; and
a controller to adjust the frequency.

2. The system of claim 1, wherein the match network is configured to match to two or more non-fifty-ohm match states.

3. The system of claim 2, wherein the match network comprises two PIN diodes to provide at least four match states.

4. The system of claim 1, wherein the exciter, the amplifier, the match network, and the controller are housed within a same chassis.

5. The system of claim 4, comprising DC protection circuitry to receive DC power from a DC power supply that is remote from the chassis.

6. The system of claim 4, comprising a DC power supply within the same chassis to provide power to, at least, the amplifier.

7. The system of claim 1 comprising:
a DC power supply to remotely power a plurality of power amplifiers via a DC bus.

8. The system of claim 1, comprising a sensor to sense current provided by the system, wherein the controller is configured to adjust the sensed current.

9. The system of claim 1, comprising a sensor to sense voltage, wherein the controller is configured to adjust the sensed voltage.

10. A system comprising:
an oscillator to provide a radio frequency signal;
at least one amplifier to amplify the radio frequency signal to produce at least one amplified radio frequency signal; and
a controller to regulate on at least one of current and voltage of the at least one amplified radio frequency signal.

11. The system of claim 10 comprising:
a match network configured to match the amplifier to at least one non-fifty-ohm match state.

12. The system of claim 11, wherein the controller is configured to control the exciter to adjust the frequency of the amplified radio frequency signal.

13. The system of claim 11, wherein the match network is configured to match to two or more non-fifty-ohm match states.

14. The system of claim 10 comprising a distributed direct current (DC) system configured to power a plurality of amplifiers.

15. The system of claim 14, comprising:
a housing enclosing the exciter and the amplifier;
wherein the distributed DC system comprises a DC power supply that is external to the housing, the DC power supply to power the plurality of amplifiers.

16. A system comprising:
a plurality of generators wherein each generator is configured to mechanically couple on chamber, wherein each generator provides an amplified signal, each generator comprising:
a match network; and
a direct current (DC) system to power the plurality of generators.

17. The system of claim 16 wherein the match network of each generator is configured to match to at least one non-fifty-ohm match state.

18. The system of claim 17 wherein the match network of each generator is configured to match to two or more non-fifty-ohm match states.

19. The system of claim 18, wherein each generator comprises an exciter to provide a signal and a controller configured to control a corresponding exciter to adjust a frequency of the signal.

20. The system of claim 17, wherein each generator comprises a controller to regulate a corresponding amplified signal on at least one of current and power.
